(19) United States
(12) Patent Application Publication
(10) Pub. No.: US 2015/0348881 A1
(43) Pub. Date: Dec. 3, 2015

(54) Solder Coated Clip And Integrated Circuit Packaging Method

(71) Applicant: TEXAS INSTRUMENTS INCORPORATED, Dallas, TX (US)

(72) Inventor: Dan Okamoto, Oita (JP)

(73) Assignee: TEXAS INSTRUMENTS INCORPORATED, Dallas, TX (US)

(21) Appl. No.: 14/290,153

(22) Filed: May 29, 2014

(51) Int. Cl. H01L 23/495; B23K 35/02; H01L 23/00; H01L 21/56; H01L 21/48

(52) U.S. Cl. CPC H01L 23/49517; H01L 23/49503; H01L 23/49541; H01L 21/565; H01L 21/4825; H01L 24/83; H01L 24/27; B23K 35/025; H01L 2224/83801; H01L 2224/2741; H01L 2224/32245

(57) ABSTRACT

A method of making a QFD package including providing a clip and coating at least a first end portion of the clip with solder paste.

### BACKGROUND

A “MOSFET” (metal-oxide semiconductor field-effect transistor) is a special type of field-effect transistor (FET) that works by electronically varying the width of a channel along which charge carriers flow. Power MOSFETS are used as electronic switches in power management applications. MOSFETS were developed in the 1980's. Vertically stacked MOSFET technology was developed in the late 2000's. A QFN (quad flat no lead) package is a type of integrated circuit package frequently used to package vertically stacked MOSFETS. In such a QFN package MOSFETS, lead frames and electrical connection clips are arranged in a vertical stack, which is covered with mold compound. The mold compound cures to form a hard, box-shaped encasement around the stack. One face of a QFN package typically has a central exposed die attachment pad and a row of exposed lead pads on opposite sides of the die attachment pad. The lead pads allow the QFN to be connected with external circuitry.

### BRIEF DESCRIPTION OF THE DRAWINGS

FIG. 1 is a partially transparent isometric view of a prior art QFD.

FIG. 2 is a cross-sectional elevation view of the prior art QFD of FIG. 1.

FIG. 3 is a bottom plan view of the prior art QFD of FIG. 1.

FIG. 4 is a magnified x-ray photograph of a clip soldered to a lead.

FIG. 5 is an example side elevation view of a clip with solder paste applied thereto.

FIG. 6 is a side elevation view of a stacked assembly of a QFD package.

FIG. 7 is a detailed elevation view of a portion of FIG. 6.

FIG. 8 is a block diagram of an embodiment of a method of making a QFD package.

FIG. 9 is a block diagram of an embodiment of a method of attaching a clip to a leadframe.

### DETAILED DESCRIPTION

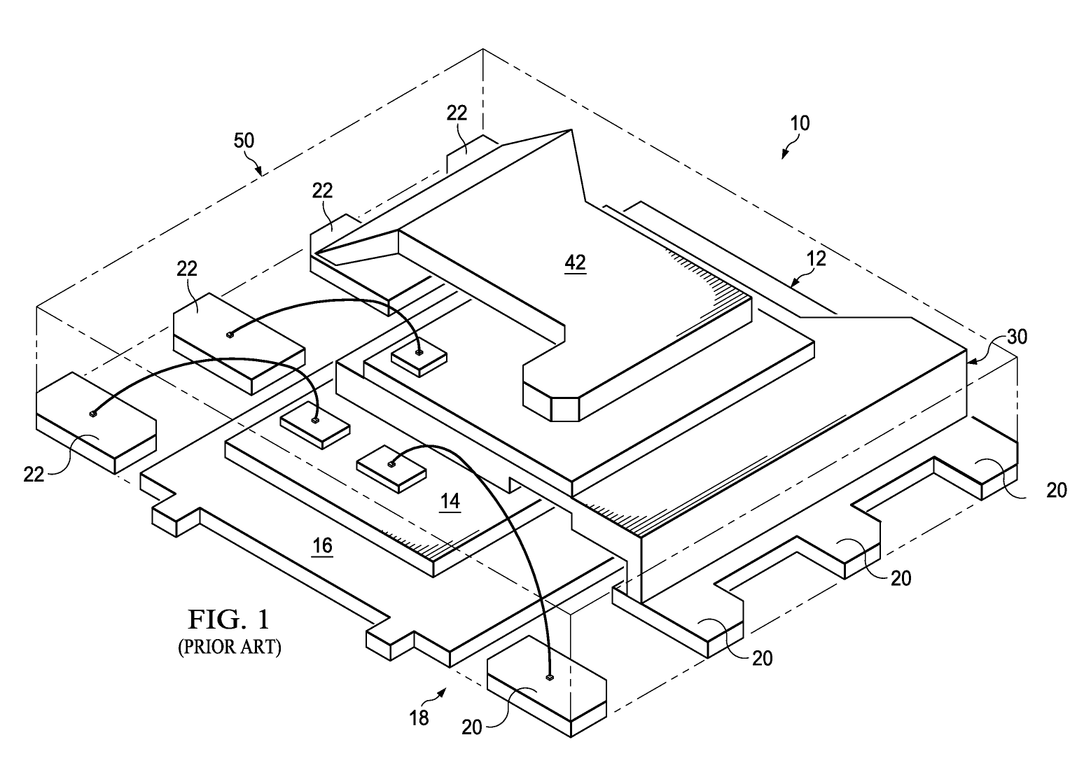

An example prior art QFN (quad flat no-lead) package 10 that uses stacked MOSFET technology is shown in FIGS. 1-3. This QFN package 10 has a high-side MOSFET die 12 (“die 12”) stacked above a low-side MOSFET die 14 (“die 14”).

The low-side die 14 is attached to a die attachment pad 16 of a lead frame 18 by a layer of solder 11. The lead frame 18 has a first plurality of leads 20 on one side of the die attachment pad 16 and another plurality of leads 22 on the opposite side of the die attachment pad 16. The die attachment pad 16 acts as a thermal pad that transfers heat out of the package. The leads 20, 22 are spaced outwardly from the die attachment pad 16. The low-side die 14 is connected to outside electrical circuitry (not shown) through a first copper clip 30 that is attached to die 14 top surface by a patch of solder 13. The first clip 30 connects the low-side die 14 to the first plurality of leads 20. The high-side die 12 is attached to the top surface of the thick copper clip 30 by a patch of solder 15. A second copper clip 42 connects the high-side die 12 to the second plurality of leads 22. The top of the high-side die 12 is attached to the bottom of the second clip 42 by another solder patch 17.

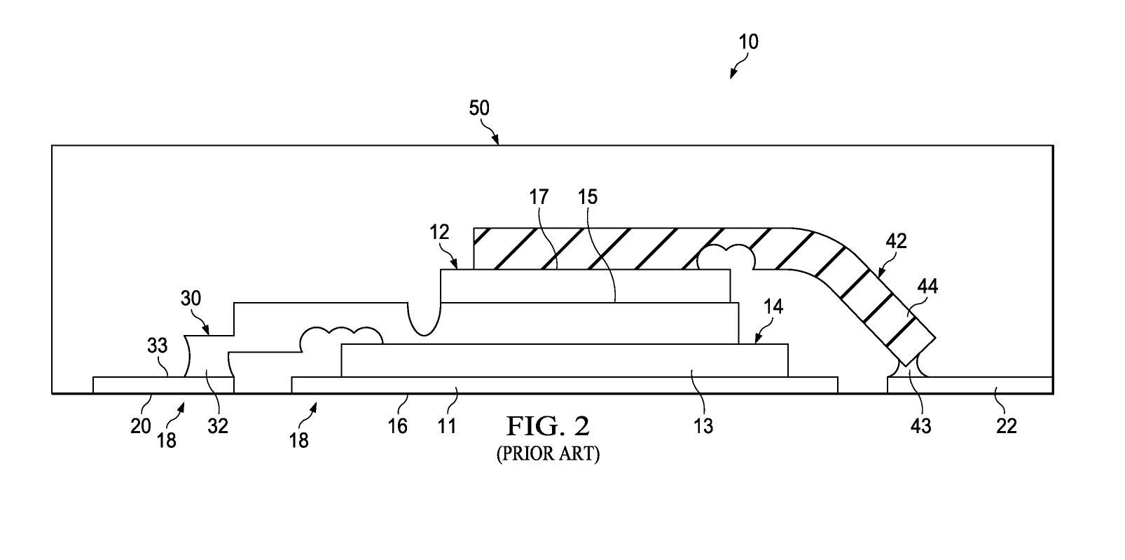

As best shown in FIG. 2 a first end portion 32 of the first clip 30 is attached to one of the first plurality of leads 20 by a plurality of solder patches 33. A first end 44 of the clip 42 is attached to the plurality the leads 22 by a plurality of solder patches 43.

The QFN package 10 has solder patches located in different positions within the QFN package 10. These solder patches are typically portions of screen-printed layers, which are applied, one layer at a time, as the stack is built up. (After the stack is built up it is transferred to a reflow furnace where the solder paste is reflowed and subsequently cooled to form solder bonds.) For example the first solder layer to be applied is applied to the top of the bottom lead frame 18. This layer includes solder patches 11 on the die attachment pad 16 and solder patches 33 on top each of the leads 20 that are attached to the first clip 30 and also solder patches 43 on the leads 22 that are attached to the second clip 42.

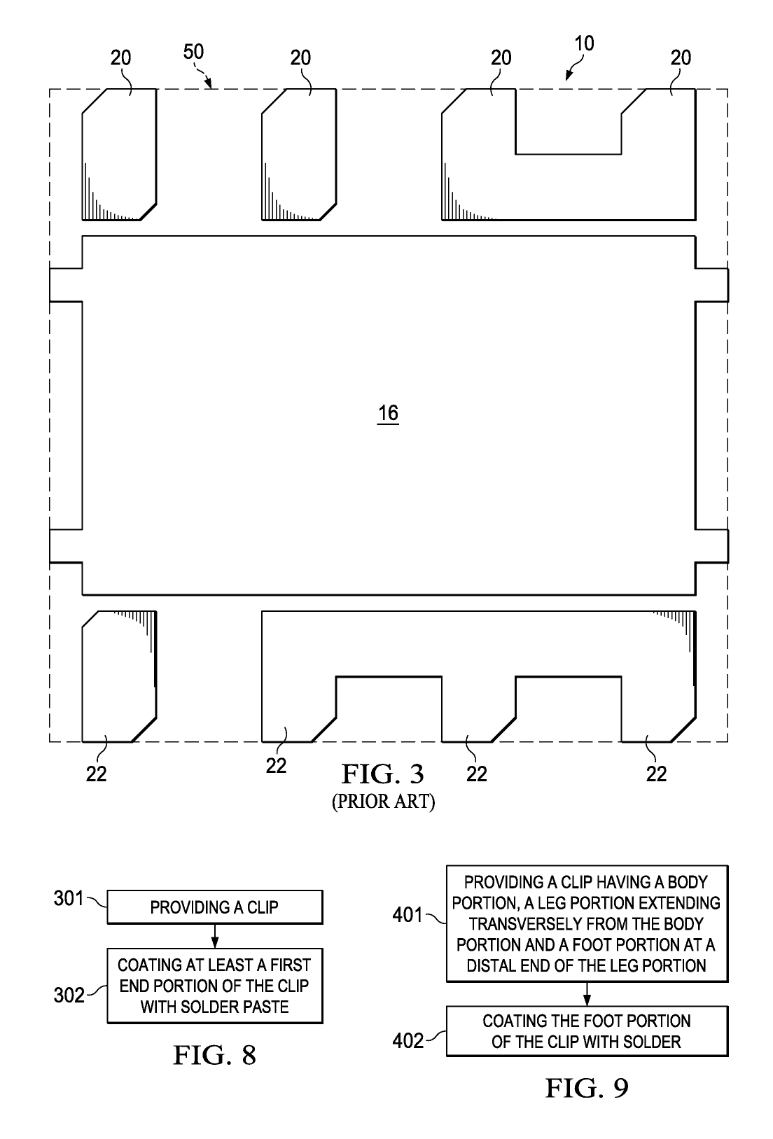

After the stack has been heated in the reflow furnace and cooled the entire stack is encapsulated in heated mold compound that cools to form a rigid epoxy encasement/box 50 around the stack. As shown by FIG. 3, each of the first and second plurality of leads 20, 22 and the die attachment pad 16 are exposed at the bottom surface of the epoxy box.

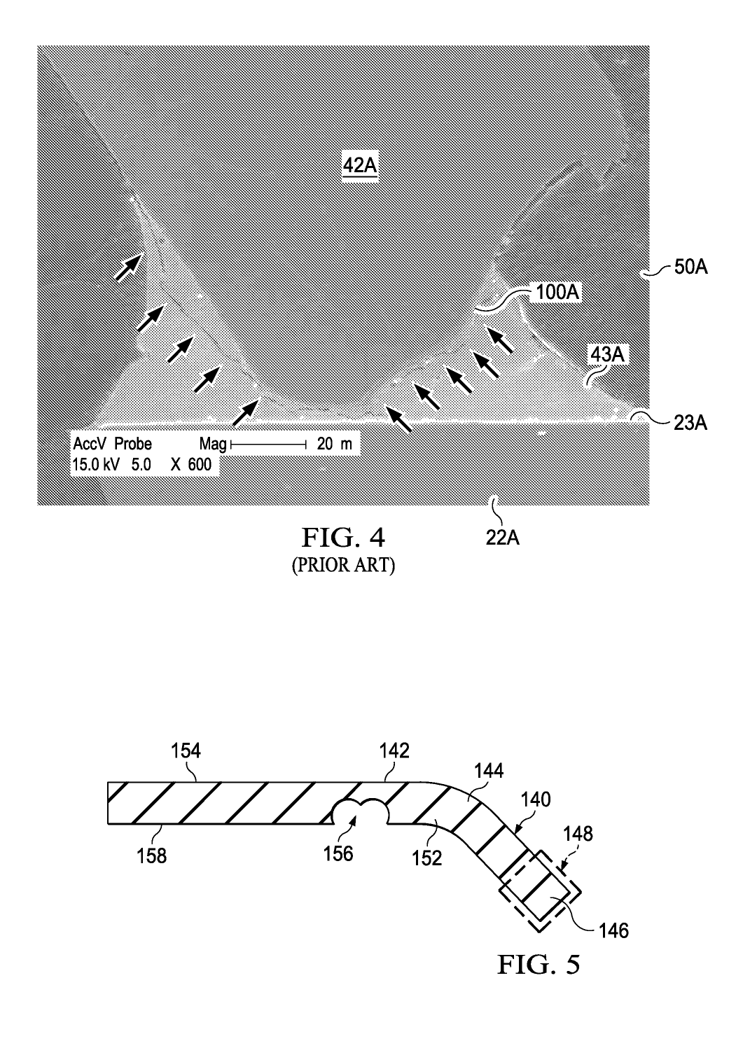

FIG. 4 is a magnified x-ray photograph made by applicant of the lower end portion of a clip 42A, similar to the clip 42 shown in FIG. 2. This photograph was taken after 1000 heating and cooling cycles of the associated QFN. A QFN typically goes through many heating and cooling cycles during ordinary operation. FIG. 4 demonstrates a problem, discovered by applicant, which may occur using prior art clip attachment methodology. The lower end portion of the clip 42A is attached to a top surface 23A of a lead 22A by a patch of solder 43A. As illustrated by the superimposed arrows, a crack 100A has propagated through the solder patch 43A in a region generally following the outline of the lower end portion of clip 42A. The solder patch 43A in this photograph did not fill in properly in a region 50A located at the lower right-hand side of the lower end portion of clip 42A. The improper solder fill in this photograph resulted from solder paste application problems during screen-printing. Applicant has discovered that such problems may be overcome by coating the lower end portion of each clip with solder paste prior to mounting it on the associated QFN stack. Coating the clip end provides better wetting of the clip surface than merely engaging the end of the clip with the solder patches applied to the leads. Also, it increases the volume of solder between the lead and the angled tip of the clip, thereby producing a better solder bond than prior art methods.

FIG. 5 is a side elevation view of a clip 140 having a body portion 142 and a leg portion 144 integrally formed with and extending transversely to the body portion 142. The leg portion terminates in a foot portion 146, which defines a first end portion of the clip 140. The foot portion 146 of the clip has a layer of solder paste 148 applied thereto, which extends the full width of the clip. (The width direction is a direction perpendicular to the plane of drawing FIG. 5.) In one embodiment the solder paste is applied by dipping the foot portion into a container filled with solder paste. In another embodiment the solder paste is applied to a plurality of aligned clips 140 by an inkjet spray head making a series of passes over the aligned clips. In another embodiment the solder paste is applied by a conventional solder dispensing head.

As further illustrated by FIG. 5, the body portion 142 may comprise a connected end region 152 integrally connected to the leg portion 144 and may also comprise a far end region 154 defining a second end of the clip 140. A relatively small thickness intermediate region 156 may be integrally formed with the normal thickness connected end region 152 and far end region 154. A lower surface 158 of the far end portion 154 is adapted to be attached to the top surface of a die as described below.

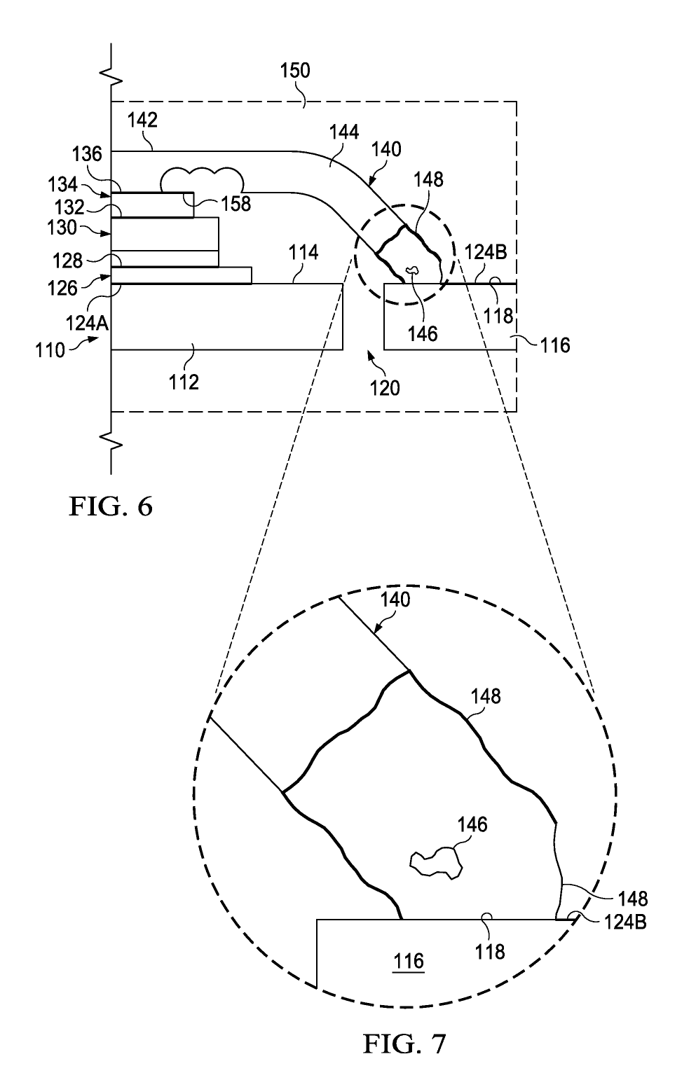

FIGS. 6 and 7 illustrate an embodiment of a QFN stack, which my be similar to the stack described with reference to FIGS. 1-3, except that one end of a top clip has been coated with solder paste before it was mounted on the stack. The QFN stack of FIG. 6 includes a first leadframe 110. The leadframe 110 comprises a die attachment pad 112 having a upper surface 114 and a plurality of leads 116 having upper surfaces 118. The QFN stack includes a lower die 126 positioned on top the die attachment pad 112, a lower clip 130 on top the lower die 126 and an upper die 134 stacked on top the lower clip 130. An upper clip 140, as described with reference to FIG. 5, is stacked on top the upper die 134 and a first end portion (foot portion) 146 is attached to a top surface 118 of associated lead portion 116. Lead portion 116 is separated from the die attachment pad 112 by a gap 120.

Screen printed portions or patches 124A and 124B of a first coat/layer of solder paste are applied to the die attachment pad top surface 114 and the lead portion top surface 118 prior to mounting of the lower die 126 on the top surface 114 of the die attachment pad 112. Also a patch 128 of a second solder paste coating/layer is applied to the top surface of the lower die 126 in a second solder paste application, as by screen printing, after the lower die 126 is mounted on the die attachment pad 112. A solder paste patch 132 of a third coating of solder paste is applied to the top surface of the lower clip 130 after it is attached to the top surface of the lower die 126. A solder paste patch 136 of a fourth coating of solder paste is applied to the top surface of the upper die 134 after it is attached to the lower clip 130. (The solder paste patches 124A, 124B, 128, 132, and 136 and the associated surfaces that each patch connects are represented by single lines in FIG. 6.

As previously mentioned the foot portion 146 of the upper clip 140 has a coating 148 of solder paste applied thereto before it is mounted on the stack. When the upper clip 140 is mounted on the stack, the lower surface 158 of its laterally extending body portion 142 engages the solder patch 136 and the solder coating/layer 148 on the foot portion (first end) 146 comes into mechanically mixing engagement with the solder paste patch 124 applied to the lead 116 top surface 118. Because the solder paste coating 148 was applied directly to the foot portion 146 prior to placing it in engagement solder paste patch 124 on the top surface 118 of lead 116, there is good solder paste coverage in the foot portion 148/top surface 128 region. It will thus be understood that the assembly of the various components of the QFN stack shown in FIG. 6, may be the same as a conventional QFN stack build up, for example, that described with reference to FIGS. 1 and 2, except that the top clip 140 has had its foot portion 146 coated with a layer of solder 148 prior to the stack build up, as best shown in FIG. 7.

After the stack build up is completed, the entire assembly is moved to a conventional reflow oven for heating to reflow the layers of solder paste and bond the associated surfaces. As best shown by FIG. 7, the foot portion 146 if bonded to lead surface 118 by the combined solder paste patch 124B and the solder paste coating 148 on foot portion 146 during this heating and subsequent cooling cycle. A strong bond is formed because all surfaces of foot portion 146 and surface 118 are well wetted by the solder paste applied thereto and because a sufficient amount of solder paste was assured by the application of solder paste coating 148. The two patches 124B and 148 flow together during the reflow process, forming a continuous unitary solder bond between the foot 146 and die pad 116.

The next step is to apply mold compound 150, shown in dashed lines in FIG. 6, to the assembly shown in solid lines in FIG. 6. This may be done in a conventional manner as described with reference to FIGS. 1 and 2.

As illustrated by FIG. 8, a method of making a QFD package includes, as shown at block 301, providing a clip; and, as shown at block 302, coating at least a first end portion of the clip with solder paste.

As illustrated by FIG. 9, a method of attaching a clip to a leadframe may include, as shown at block 401, providing a clip having a body portion, a leg portion extending transversely from the body portion and a foot portion at a distal end of the leg portion. The method also includes, as shown at 402, coating the foot portion of the clip with solder.

Specific embodiments of a QFN package produced by us of a clip with a separately coated end portion have been expressly described in detail herein. It will be obvious to those skilled in the art after reading this disclosure that other semiconductor package embodiments having one or more clips with at least one separately coated end could be otherwise embodied and made. It is intended that the appended claims be broadly construed to cover all such alternative embodiment, except as limited by the prior art.

What is claimed is:

1. A method of making a QFD package comprising:
providing a clip;
coating at least a first end portion of the clip with solder paste.

2. The method of claim 1 further comprising:
providing a lead frame with at least one lead portion; and
applying a patch of solder paste to the lead portion of the lead frame.

3. The method of claim 2 further comprising:
placing the solder paste coated end portion of the clip in engagement with the patch of solder paste on the lead portion.

4. The method of claim 3 further comprising heating the clip and the lead portion and the associated solder paste to form a solder bond between the clip and the lead portion.

5. The method of claim 4 further comprising covering the solder bonded clip and lead portion with mold compound.

6. The method of claim 2 wherein said providing a lead frame comprises providing a lead frame with at least one lead portion and one die attachment pad portion and further comprising attaching a component stack including at least a top die to the die attachment pad portion and applying a patch of solder paste to a top surface of the top die.

7. The method of claim 6 further comprising placing an end portion of the clip opposite to the coated first end portion in engagement with the patch of solder paste on the top surface of the top die and placing the solder paste coated first end portion of the clip in engagement with the patch of solder paste on the lead portion.

8. The method of claim 7 further comprising heating the clip and the lead frame and the top die to solder bond the clip to the top die and to solder bond the clip to the lead portion.

9. The method of claim 8 further comprising covering the component stack, the lead frame and the clip with die compound.

10. A method of attaching a clip to a leadframe comprising:
providing a clip having a body portion, a leg portion extending transversely from the body portion and a foot portion at a distal end of the leg portion;
coating the foot portion of the clip with solder paste prior to placing the foot portion into engagement with a lead.

11. The method of claim 10 wherein coating the foot portion comprises spraying solder paste onto the foot portion.

12. The method of claim 10 wherein coating the foot portion comprises dispensing solder paste onto the foot portion.

13. The method of claim 10 wherein applying solder paste to the foot portion comprises dipping the foot portion in solder paste.

14. The method of claim 10 further comprising:
coating a portion of the leadframe with solder paste; and
contacting the coated portion of the leadframe with the coated foot portion of the clip.

15. The method of claim 14 further comprising heating the leadframe and the foot portion.

16. The method of claim 8 wherein heating the leadframe and the foot portion comprises heating the leadframe and the foot portion in a reflow furnace.

17. An intermediate product made in the production of a QFN package comprising a clip having a solder paste coated foot portion.

18. The intermediate product of claim 18 further comprising a leadframe having a solder paste coated lead portion positioned in spaced relationship with the solder coated foot portion.

19. The intermediate product of claim 17 further comprising a leadframe having a solder paste coated lead portion positioned in engaged relationship with the solder paste coated foot portion.

20. The intermediate product of claim 17 wherein the engaged coated lead portion and coated foot portion are in an engaged melting and mixing relationship.
